(19) United States
(12) Patent Application Publication
(10) Pub. No.: US 2025/0275139 A1
(43) Pub. Date: Aug. 28, 2025

(54) VERTICAL NONVOLATILE MEMORY DEVICE AND METHOD OF MANUFACTURING THE SAME

(71) Applicant: Samsung Electronics Co., Ltd., Suwon-si (KR)

(72) Inventors: Minhyun LEE, Suwon-si (KR); Jinjoo PARK, Suwon-si (KR); Seonghun JANG, Suwon-si (KR); Seokhoon CHOI, Suwon-si (KR)

(73) Assignee: Samsung Electronics Co., Ltd., Suwon-si (KR)

(21) Appl. No.: 18/999,223

(22) Filed: Dec. 23, 2024

(30) Foreign Application Priority Data
Feb. 26, 2024 (KR) 10-2024-0027498

(51) Int. Cl. H10B 43/27; H10B 43/10; H10B 43/35; H10D 30/01; H10D 30/69; H10D 64/01

(52) U.S. Cl. CPC H10B 43/27; H10B 43/35; H10D 30/0413; H10D 30/693; H10D 30/694; H10D 64/037; H10B 43/10

(57) ABSTRACT

Provided is a memory device including a plurality of cell strings, wherein each of the plurality of cell strings includes a channel layer, a charge tunneling layer, a plurality of charge trap layers, a plurality of charge blocking layers, and a plurality of gate electrodes, which are arranged in a lateral direction, and a plurality of separation layers configured to isolate the plurality of charge trap layers, the plurality of charge blocking layers, and the plurality of gate electrodes from each other in a longitudinal direction, and the plurality of separation layers each independently include at least one of germanium (Ge), tin (Sn) or carbon (C) in a region where the plurality of separation layers are in contact with the plurality of gate electrodes.

### CROSS-REFERENCE TO RELATED APPLICATION

This application is based on and claims priority under 35 U.S.C. § 119 to Korean Patent Application No. 10-2024-0027498, filed on Feb. 26, 2024, in the Korean Intellectual Property Office, the disclosure of which is incorporated by reference herein in its entirety.

### BACKGROUND

One or more example embodiments relate to a vertical nonvolatile memory device and/or a method of manufacturing the same.

Nonvolatile memory devices maintain information even when the supply of power is cut off. A nonvolatile memory device includes a plurality of memory cells in which stored information may be used again when power is supplied to the nonvolatile memory device. Such nonvolatile memory devices may be widely applied to one or more of mobile phones, digital cameras, personal digital assistants (PDAs), mobile computer devices, and the like.

Recently, as highly-integrated and low-power consumption nonvolatile memory devices are required or desired, vertical NAND (VNAND) flash memory devices have been developed. In VNAND flash memory devices, a charge movement between the memory cells may occur due to an increase in the stack number and/or a height reduction of the memory cells, and such charge movement may deteriorate the charge retention characteristics of the memory cells.

### SUMMARY

One or more example embodiments include a vertical nonvolatile memory device having enhanced charge retention characteristics of memory cells, and/or a method of manufacturing the vertical nonvolatile memory device.

Additional aspects will be set forth in part in the description which follows and, in part, will be apparent from the description, or may be learned by practice of the presented embodiments of the disclosure.

According to one or more example embodiments, a memory device includes a plurality of cell strings, wherein each of the plurality of cell strings may include a channel layer, a charge tunneling layer outside the channel layer in a lateral direction perpendicular to a longitudinal direction of the channel layer, a plurality of charge trap layers in the lateral direction outside the charge tunnel layer spaced apart from the charge tunneling layer in the longitudinal direction, a plurality of charge blocking layers in the lateral direction respectively outside the plurality of charge trap layers in, and a plurality of separation layers configured to isolate the plurality of charge trap layers, the plurality of charge blocking layers, and the plurality of gate electrodes from each other in the longitudinal direction, and the plurality of separation layers each may independently include one or more of germanium (Ge), tin (Sn) or carbon (C) in a region where the plurality of separation layers are in contact with the plurality of gate electrodes.

Alternatively or additionally according to one or more example embodiments, a method of manufacturing a memory device includes stacking a plurality of separation layers and a plurality of semiconductor material layers on a substrate alternately, forming through holes to pass through the plurality of separation layers and the plurality of semiconductor material layers, forming a plurality of recesses by selectively etching a part of the plurality of semiconductor material layers at inner walls of the through holes, forming a plurality of charge trap layers for filling the plurality of recesses, sequentially forming a charge tunneling layer and a channel layer at the inner walls of the through holes, etching the plurality of remaining semiconductor material layers, forming a plurality of charge blocking layers by oxidizing a part of an outside of the plurality of charge trap layers, and forming a plurality of gate electrodes in a region where the plurality of remaining semiconductor material layers are etched, wherein the separation layers each may include germanium (Ge), tin (Sn) or carbon (C) in a region where the plurality of separation layers are in contact with the plurality of gate electrodes.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a vertical nonvolatile memory device according to some example embodiments;

FIG. 2 is a cross-sectional view of the vertical nonvolatile memory device taken along a line A1-A1′ of FIG. 1;

FIG. 3 is an enlarged view of a portion MC of FIG. 1;

FIG. 4 is a partially-enlarged view illustrating a modified example of the portion MC of FIG. 1;

FIG. 5 is a partially-enlarged view illustrating a modified example of a portion X of FIG. 1;

FIG. 6 is a circuit diagram including a vertical nonvolatile memory device according to some example embodiments;

FIGS. 7A through 7H are views illustrating a method of manufacturing a vertical nonvolatile memory device according to some example embodiments;

FIGS. 8A and 8B are views illustrating a part of a method of manufacturing a vertical nonvolatile memory device according to some example embodiments;

FIGS. 9A and 9B are graphs showing a reduction in a leakage current of an interlayer insulating layer of a memory device according to a comparative example and some example embodiments, respectively;

FIG. 10 is a block diagram of a display driver integrated circuit (IC) (DDI) and a display apparatus including a DDI according to some example embodiments;

FIG. 11 is a block diagram illustrating an electronic apparatus according to some example embodiments;

FIG. 12 is a block diagram illustrating an electronic apparatus according to some example embodiments; and

FIGS. 13 and 14 are conceptual views schematically illustrating a device architecture that may be applied to an electronic apparatus according to some example embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a vertical nonvolatile memory device and a method of manufacturing the same according to other embodiments will be described in detail with reference to the accompanying drawings. In the following drawings, the same reference numerals refer to the same component, and the size of each component in the drawings may be exaggerated for clarity and convenience of explanation. In addition, embodiments to be described below are only an example, and various variations are possible from these embodiments.

Hereinafter, when a portion is described as “above” or “on” another portion may include the case where the portion is above or on another portion in a non-contact manner, as well as directly above or on another portion in a contact manner. The singular expression includes a plurality of expressions unless the context is clearly different. In addition, when a portion “includes” a component, it means that it may further include other components, not excluding other components unless particularly stated to the contrary.

The use of the terms of “above” and the use of similar indicators may correspond to both singular and plurality. If the order is clearly described for steps for configuring a method or there is no opposite description, these steps can be performed in the right order, and are not necessarily limited to the order described.

Connections or connection members of lines between components shown in the drawings show functional connections and/or physical or circuit connections, which are shown as replaceable or additional functional connections, physical connections or circuit connections in an actual devices.

The use of all examples or exemplary terms is intended simply to describe the technical spirit in detail in detail, and the scope is not limited due to these examples or exemplary terms unless it is limited by the claims.

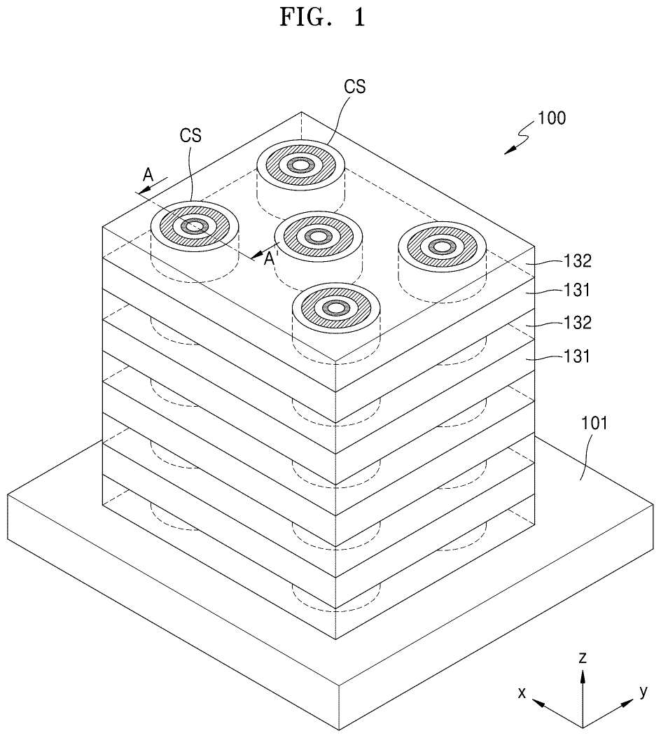

FIG. 1 is a schematic perspective view of a vertical nonvolatile memory device according to some example embodiments.

Referring to FIG. 1, a vertical nonvolatile memory device 100 may include a plurality of cell strings CS arranged on a substrate 101. The plurality of cell strings CS may extend in a direction (z-axis direction) perpendicular to the substrate 101. The plurality of cell strings CS of various forms may be arranged on the substrate 101.

The substrate 101 may be or may include one or more of a monocrystalline silicon substrate, a compound semiconductor substrate, or a silicon on insulator (SOI) substrate, but embodiments are not limited thereto. A gate electrode 131 and a separation layer 132 may be alternately stacked on the substrate 101.

A number of and/or a thickness of each of the gate electrode layers 131 and/or the separation layers 132 are not limited to what is illustrated in FIG. 1. For example, a thickness of each of the gate electrode layers 131 and each of the separation layers 132 may be the same, or, at least one of the gate electrode layers 131 and/or the separation layers 132 may have a different thickness than others of the gate electrode layers 131 and/or the separation layers 132. Additionally or alternatively, each of the cell strings CS may be arranged as a lattice, such as a rectangular (e.g., square) or triangular or hexagonal lattice such as a regular triangular or regular hexagonal lattice; example embodiments are not limited thereto.

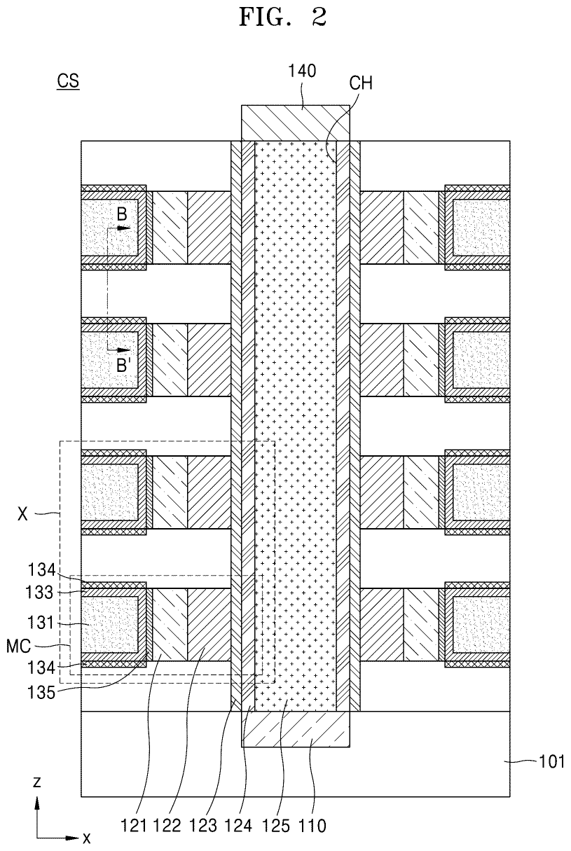

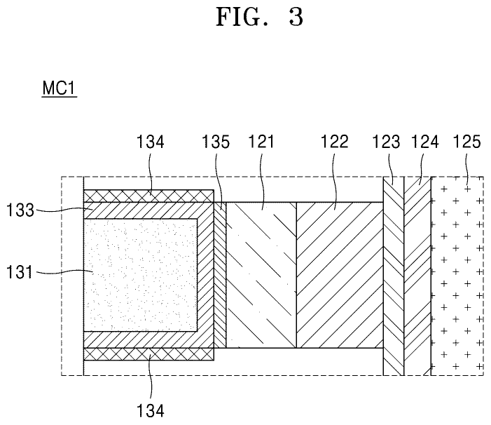

FIG. 2 is a cross-sectional view of the vertical nonvolatile memory device taken along a line A-A′ of FIG. 1, and FIG. 3 is an enlarged view of a portion MC of FIG. 1.

Referring to FIGS. 2 and 3, each cell string CS may include a plurality of memory cells MC stacked in the direction (z-axis direction) perpendicular to the substrate 101. The memory cell MC may be a basic unit cell for writing and erasing data.

Each of the plurality of cell strings CS may include or may define a channel hole CH that perforates a stack body of the gate electrode 131 and the separation layer 132 in the direction (z-axis direction) perpendicular to the substrate 101. Each of the channel holes CH may be formed to have a circular cross-section or circular shape in viewed in plan, for example. However, the cross-sectional shape of the channel hole CH is not limited thereto; for example, a shape of the channel hole may be elliptical. A region excluding the gate electrode 131 and the separation layer 132 from the cell string CS may have a structure in which a plurality of material layers having a cylindrical cell shape are stacked outwardly from the channel hole CH.

The plurality of material layers having a cylindrical shell shape or a tapered cylindrical shell shape may form the memory cell MC. For example, the cell string CS may include a plurality of memory cells MC arranged in the z-axis direction. A part of the plurality of material layers forming each memory cell MC may be isolated by the separation layer 132 from a corresponding material layer of another memory cell MC in the z-axis direction. However, the structure of the cell string CS is not limited thereto, and the cell string CS may have a different shape and a different structure.

The cell string CS may include a channel layer 124, a charge tunneling layer 123, a plurality of charge trap layers 122, a plurality of charge blocking layers 121, and a plurality of gate electrodes 131. The channel layer 124, the charge tunneling layer 123, the charge trap layer 122, the charge blocking layer 121, and the gate electrode 131 may form (or may correspond to) a single memory cell MC.

In the cell string CS according to some example embodiments, the plurality of memory cells MC may share the channel layer 124 and the charge tunneling layer 123. The remaining material layers of the plurality of memory cells MC may be isolated by or insulated by a plurality of separation layers 132 in a longitudinal direction of the channel layer 124, i.e., in the z-axis direction.

For example, the charge tunneling layer 123 may be provided outside the channel layer 124 in a lateral direction perpendicular to the longitudinal direction (z-axis direction) of the channel layer 124. The charge tunneling layer 123 may surround an outer circumferential surface of the channel layer 124 in the lateral direction. The charge tunneling layer 123 may extend in the longitudinal direction. The plurality of charge trap layers 122 may be provided outside the charge tunneling layer 123 in the lateral direction to be spaced apart from the charge tunneling layer 123 in the longitudinal direction. Each charge trap layer 122 may surround the charge tunneling layer 123. The plurality of charge blocking layers 121 may be provided outside each of the plurality of charge trap layers 122 in the lateral direction. Each charge blocking layer 121 may surround the charge trap layer 122 that corresponds to the charge blocking layer 121. The plurality of gate electrodes 131 may be provided outside each of the plurality of charge blocking layers 121 in the lateral direction. The plurality of separation layers 132 may be configured to isolate the plurality of charge trap layers 122, the plurality of charge blocking layers 121, and the plurality of gate electrodes 131 in the longitudinal direction of the channel layer 124.

A source electrode 110 and a drain electrode 140 may be provided at both ends of the channel layer 124 in the longitudinal direction. The source electrode 110 may be commonly connected to the plurality of cell strings CS. When a certain voltage (e.g., a positive voltage or a negative voltage) is applied to the gate electrode 131 of the memory cell MC, a channel may be formed in an inner region of the channel layer 124 facing the gate electrode 131, and charges flowing between the source electrode 110 and the drain electrode 140 may pass through the charge tunneling layer 123 and may be captured in the charge trap layer 122 so that information may be stored in the memory cell MC.

The channel layer 124 may include a semiconductor material. The channel layer 124 may include, for example, one or more of silicon (Si), germanium (Ge), silicon germanium (SiGe), a III-V-group semiconductor, and the like. Alternatively or additionally, the channel layer 124 may include, for example, one or more of an oxide semiconductor, a nitride semiconductor, an oxynitride semiconductor, a two-dimensional (2D) semiconductor material, a quantum dot, or an organic semiconductor. The oxide semiconductor may include, for example, InGaZnO and/or the like. In some example embodiments, the 2D semiconductor material may include, for example, transition metal dichalcogenide or graphene, and the quantum dot may include one or more of a colloidal quantum dot (QD), a nanocrystal structure, or the like. The 2D semiconductor material may refer to a semiconductor material having a 2D crystalline structure, and may have a monolayer or multilayer structure. The 2D semiconductor material has good or excellent electrical characteristics, and may be a material that may be applied to various devices, because, even when the thickness of the 2D semiconductor material is small in a nano scale, the characteristics of the 2D semiconductor material are not greatly changed and high mobility thereof is maintained. Each layer that constitutes the 2D semiconductor material may have a thickness of an atomic level. The 2D semiconductor material may include, for example, at least one of graphene, black phosphorous, and transition metal dichalcogenide (TMD). Graphene is a substance in which carbon atoms are combined in two dimensions to have a hexagonal honeycomb structure, has high electrical mobility and good or excellent thermal characteristics compared to Si, is chemically stable, and has a large surface area. Black phosphorus (BP) is a substance in which black phosphorous atoms are combined in two dimensions.

TMD may be expressed as MX₂, for example, where M represents a transition metal, and X represents a chalcogen element. For example, M may include (one or more of) molybdenum (Mo), tungsten (W), niobium (Nb), vanadium (V), tantalum (Ta), titanium (Ti), zirconium (Zr), hafnium (Hf), technetium (Tc), or rhenium (Re), and X may include sulfur(S), selenium (Se), or tellurium (Te). Thus, for example, TMD may include (one or more of) MoS₂, MoSe₂, MoTe₂, WS₂, WSe₂, WTe₂, ZrS₂, ZrSe₂, HfS₂, HfSe₂, NbSe₂, or ReSe₂.

Alternatively or additionally, the 2D semiconductor material may include CuS, which is a compound of copper (Cu) as a transition metal and S as a chalcogen element. The 2D semiconductor material may be a chalcogenide material including a non-transition metal. The non-transition metal may include, for example, one or more of gallium (Ga), indium (In), tin (Sn), germanium (Ge), lead (Pb), or the like. In this case, the 2D semiconductor material may include a compound of a non-transition metal such as Ga, In, Sn, Ge, PB, or the like and a chalcogen element such as S, Se, or Te. For example, the 2D semiconductor material may include one or more of SnSe₂, GaS, GaSe, GaTe, GeSe, In₂Se₃, InSnS₂ or the like. However, the above-mentioned materials are just examples, and other materials may also be used as the 2D semiconductor material.

The channel layer 124 may further include a dopant. Here, the dopant may include a p-type dopant or a n-type dopant (or, in some cases a p-type dopant at a first concentration and an n-type dopant at a second concentration, much greater or much less than the p-type dopant concentration). The p-type dopant may include, for example, a Ill-group element such as one or more of boron (B), aluminum (Al), gallium (Ga), indium (In) or the like, and the n-type dopant may include, for example, a V-group element such as one or more of phosphorus (P), arsenic (As), antimony (Sb) or the like.

The channel layer 124 according to various example embodiments may have a cylindrical shape, and the channel hole CH may be provided inside the channel layer 124. A pillar 125 may be provided inside the channel hole CH. The pillar 125 may include, for example, silicon dioxide (SiO₂), air such as clean, dry air, or the like, but embodiments are not limited thereto.

The charge tunneling layer 123 may be provided between the channel layer 124 and the charge trap layer 122, and may be a layer in which tunneling of charges is performed between the channel layer 124 and the charge trap layer 122, and the charge tunneling layer 123 may include, for example, silicon oxide and/or metal oxide, but embodiments are not limited thereto.

The charge trap layer 122, the charge blocking layer 121, and the gate electrode 131 may be sequentially arranged outside the charge tunneling layer 123 in the lateral direction. The plurality of gate electrodes 131 may be isolated from each other by the separation layer 132.

The charge trap layer 122 may store introduced charges. Charges (e.g., electrons or holes) that are present in the channel layer 122 may be introduced into the charge trap layer 122 by a tunneling effect or the like. The charges introduced into the charge trap layer 122 may be fixed to the charge trap layer 122. The charge trap layer 122 may include silicon and/or silicon nitride. Silicon may be, for example, crystalline silicon and/or polysilicon, which may or may not be doped.

The charge blocking layer 121 may function as a barrier for preventing or reducing charge movement between the charge trap layer 122 and the gate electrode 131. One surface of the charge blocking layer 121 may be in contact with the charge trap layer 122, and another surface of the charge blocking layer 121 may be in contact with the gate electrode 131. The charge blocking layer 121 may include an oxide of a material contained in the charge trap layer 122. The charge blocking layer 121 may include a silicon oxide and/or a silicon oxynitride, but embodiments are not limited thereto. The charge blocking layer 121 may also include one or more of a metal oxide, a metal nitride, an aluminum oxide, a magnesium oxide, an aluminum nitride, or a gallium nitride.

The gate electrode 131 may control a corresponding region of the channel layer 124. Word lines (or rows) may be electrically connected to the gate electrode 131. The gate electrode 131 may include, for example, one or more of a metal material having excellent electrical conductivity, conductive oxide, metal nitride, silicon doped with impurities, or a 2D conductive material, or the like. The metal materials may include, for example, gold (Au), titanium (Ti), TaN, TiN, tungsten (W), Mo, WN, platinum (Pt), NbN or nickel (Ni), or an arbitrary combination thereof. The conductive oxide may include, for example, one or more of indium tin oxide (ITO), indium zinc oxide (IZO), indium zinc oxide (IZO), or the like. However, this is just an example, and the gate electrode 131 may include other various materials.

The plurality of separation layers 132 may function as a spacer for isolating the plurality of charge trap layers 122, the plurality of charge blocking layers 121, and the plurality of gate electrodes 131 in the longitudinal direction of the channel layer 124. The separation layers 132 may include, for example, silicon oxide, silicon nitride, or the like, but embodiments are not limited thereto.

A region in which the separation layers 132 are in contact with the gate electrodes 131, may be referred to as a first region 134. The separation layers 132 may include one, two, or all three of Ge, Sn, or C in the first region 134 where the separation layers 132 are in contact with the gate electrodes 131. The separation layers 132 may include 1 wt % or more of Ge, Sn, or C in the first region 134 where the separation layers 132 are in contact with the gate electrodes 131.

A region in which the charge blocking layers 121 are in contact with the gate electrodes 131, may be referred to as a second region 135. The charge blocking layers 121 may include one, two, or all three of Ge, Sn, or C in the second region 135 where the charge block layers 121 are in contact with the gate electrodes 131. The content of Ge, Sn, or C in the second region 135 may be different from the content of the respective one of Ge, Sn, or C in the first region 134.

In some examples, a high-permittivity diffusion reduction layer or high-permittivity prevention layer 133 may be provided between the gate electrode 131 and the charge blocking layer 121. The high-permittivity diffusion prevention layer 133 may be provided between the gate electrode 131 and the separation layer 132. The high-permittivity diffusion prevention layer 133 may prevent or reduce the interfacial reaction between the gate electrode 131 and the charge trap layer 122 and diffusion of atoms. The high-permittivity diffusion prevention layer 133 may be configured to increase an adhesive force between two adjacent material layers, for example, between the gate electrode 131 and the charge blocking layer 121, and between the gate electrode 131 and the separation layer 132. The high-permittivity diffusion prevention layer 133 may be configured to prevent or reduce one or more of power consumption, temperature increase, degradation of operating characteristics of the memory device 100 and/or the like by reducing or improving electrical resistance at a contact surface between two material layers. The high-permittivity diffusion prevention layer 133 may include a material of the separation layer 132, for example, a material having a greater oxidation-reduction potential than an oxidation-reduction potential of silicon oxide. The high-permittivity diffusion prevention layer 133 may include, for example, one or more of AlO, HfO, ZrO, AlN, AlSCN, AlBN, HfZrO, or HfSiO.

When the high-permittivity diffusion prevention layer 133 is provided between the gate electrode 131 and the separation layer 132, the first region 134 may refer to a region in which the separation layer 132 is in contact with the high-permittivity diffusion prevention layer 133. When the high-permittivity diffusion prevention layer 133 is provided between the gate electrode 131 and the charge blocking layer 121, the second region 135 may refer to a region in which the charge blocking layer 121 is in contact with the high-permittivity diffusion prevention layer 133.

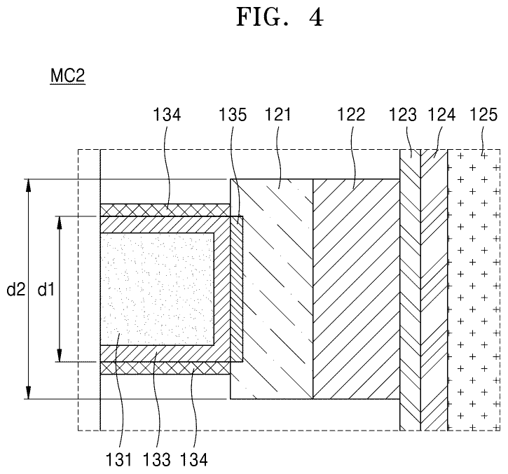

FIG. 4 is a partially-enlarged view illustrating a modified example of the portion MC of FIG. 1.

Referring to FIG. 4, a memory cell MC2 may include a channel layer 124, a charge tunneling layer 123, a charge trap layer 122, a charge blocking layer 121, and a gate electrode 131.

A thickness d2 of the charge trap layer 122 and the charge blocking layer 121 that constitute or corresponds to the memory cell MC2 in the z-axis direction may be greater than a thickness d1 of the gate electrode 131 in the z-axis direction.

When the high-permittivity diffusion prevention layer 133 is provided between the gate electrode 131 and the separation layer 132, the thickness d2 of the charge trap layer 122 and the charge blocking layer 121 in the z-axis direction may be greater than the thickness d1 of the gate electrode 131 and the high-permittivity diffusion prevention layer 133 that surrounds the gate electrode 131 in the z-axis direction.

The memory cell MC2 of FIG. 4 may be the same as the memory cell MC1 described above with reference to FIGS. 2 and 3 except that the thickness d2 of the charge trap layer 122 and the charge blocking layer 121 in the z-axis direction is greater than the thickness d1 of the gate electrode 131 in the z-axis direction. When describing FIG. 4, redundant descriptions with FIGS. 2 and 3 will be omitted.

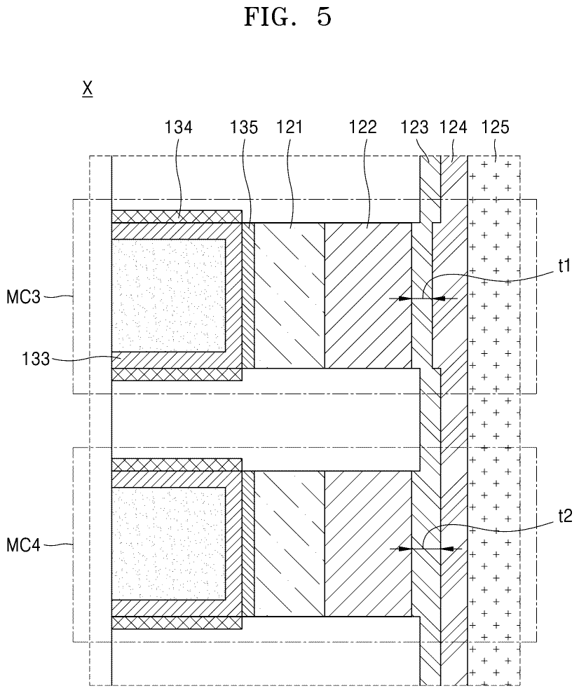

FIG. 5 is a partially-enlarged view illustrating a modified example of a portion X of FIG. 1.

Referring to FIG. 5, a plurality of memory cells MC3 and MC4 may include a channel layer 124, a charge tunneling layer 123, a charge trap layer 122, a charge blocking layer 121, and a gate electrode 131.

Thicknesses t1 and t2 of the charge tunneling layer 123 that constitutes or corresponds to the plurality of memory cells MC3 and MC3 in the lateral direction may be different from each other. A deviation between the thicknesses t1 and t2 of the charge tunneling layer 123 that constitutes or corresponds to the plurality of memory cells MC3 and MC4 in the lateral direction may occur, for example, depending on a process of forming the charge tunneling layer 123.

A deviation in thicknesses of the charge tunneling layer 123 in the lateral direction may be about 5 nm or less. For example, the charge tunneling layer 123 may also be formed by oxidizing (e.g., thermally oxidizing) the silicon charge trap layer 122, and the charge tunneling layer 123 including silicon oxide may alternatively or additionally be formed by an atomic layer deposition (ALD) process, and the charge tunneling layer 123 may also be formed by mixing the above-described methods, and a deviation in thicknesses of the charge tunneling layer 123 in the lateral direction may be reduced through these formation methods.

The cell string CS of FIG. 5 may be the same as the cell string CS described above with reference to FIGS. 2 and 3 except that thicknesses t1 and t2 of the charge tunneling layer 123 in the lateral direction that constitutes the plurality of memory cells MC3 and MC4 are different from each other. When describing FIG. 5, redundant descriptions with FIGS. 2 and 3 will be omitted.

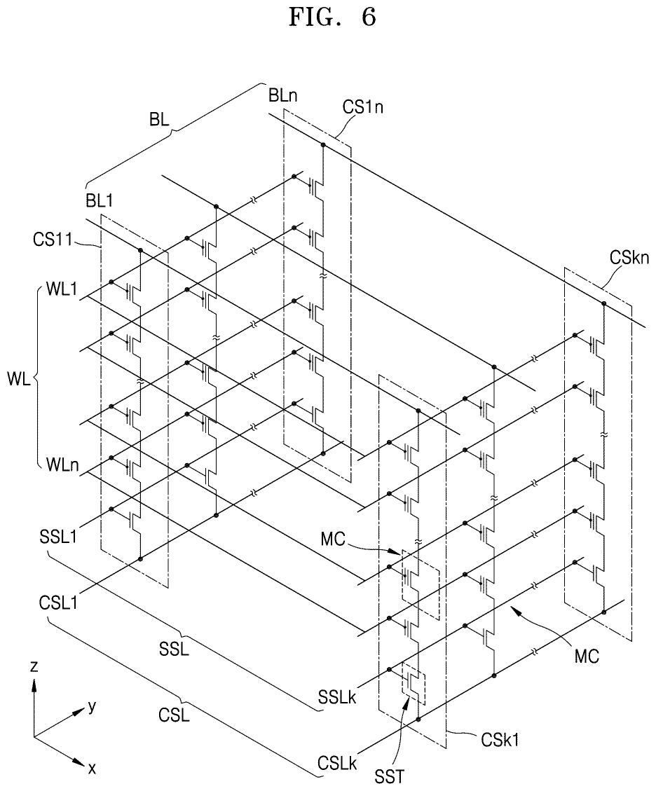

FIG. 6 is a circuit diagram including a vertical nonvolatile memory device according to some example embodiments.

Referring to FIG. 6, k*n cell strings CS may be provided and arranged in a matrix form, and may be referred to as CSij (1≤i≤k, 1≤j≤n) depending on each row, a column position. In various example embodiments, k may be greater than, less than, or equal to n. Each cell string CSij may be connected to a bit line BL, a string selection line SSL, a word line WL, and a common source line CSL.

Each cell string CSij may include memory cells MC and a string selection transistor SST. The memory cells MC and the string selection transistor SST of each cell string CSij may be stacked in a height direction.

Rows (e.g., word lines) of the plurality of cell strings CS may be connected to different string selection lines SSL1 to SSLk. For example, the string selection transistors SST of the cell strings CS11 to CS1n may be commonly connected to the string selection line SSL1. The string selection transistors SST of the cell strings CSK1 to CSkn may be commonly connected to the string selection line SSLk.

Rows of the plurality of cell strings CS may be connected to different columns (e.g., bit lines) BL1 to BLn. For example, the memory cells MC and the string selection transistors SST of the cell strings CS11 to CSk1 may be commonly connected to the bit line BL1, and the memory cells MC and the string selection transistors SST of the cell strings CS1n to CSkn may be commonly connected to the bit line BLn.

Rows of the plurality of cell strings CS may be connected to different common source lines CSL1 to CSLk. For example, the string selection transistors SST of the cell strings CS11 to CS1n may be commonly connected to the common source line CSL1, and the string selection transistors SST of the cell strings CSk1 to CSkn may be commonly connected to the common source line CSLk.

The memory cells MC disposed at the same height from the substrate 101 or the string selection transistors SST may be commonly connected to one word line WL, and the memory cells MC disposed at different heights may be connected to different word lines WL1 to WLn, respectively.

The illustrated circuit structure is an example. For example, the number of rows of the cell strings CS may be increased or decreased. As the number of rows of the cell strings CS is changed, the number of string selection lines connected to the rows of the cell strings CS and/or the number of cell strings CS connected to one bit line BL may also be changed. As the number of the rows of the cell strings CS is changed, the number of common source lines connected to the rows of the cell strings CS may also be changed.

The number of columns of the cell strings CS may also be increased or decreased. As the number of columns of the cell strings CS is changed, the number of bit lines BL connected to the columns of the cell strings CS and/or the number of cell strings CS connected to one string selection line may also be changed.

The height of the cell strings CS may also be increased or decreased. For example, the number of memory cells MC stacked in each of the cell strings CS may also be increased or decreased. As the number of memory cells MC stacked in each of the cell strings CS is changed, the number of word lines WL may also be changed. For example, the number of string selection transistors provided to each of the cell strings CS may be increased. As the number of string selection transistors provided to each of the cell strings CS is changed, the number of string selection lines and/or common source lines may also be changed. When the number of string selection transistors SST is increased, the string selection transistors SST may be stacked in the same form as the memory cells MC.

For example, writing and reading may be performed in units of rows of the cell strings CS. The cell strings CS may be selected by the common source line CSL in units of one row, and the cell strings CS may be selected by the string selection lines SSL in units of one row. In addition, a voltage may be applied to at least two common source lines CSL in one unit. Alternatively, in some cases, a voltage may be applied to all of the common source lines CSL in one unit.

In the selected row of the cell strings CS, writing and reading may be performed in units of pages. A page may be one row of memory cells connected to one word line WL. In the selected row of the cell strings CS, memory cells may be selected by word lines WL in units of pages. For example, each gate electrode 131 of FIG. 1 may be connected to one of a word line WL and a string selection line SSL.

The memory cell MC may have a circuit structure in which a transistor including gate electrodes 131, separation layers 132 and channel layers 124 is connected to the charge trap layer 122.

The memory cells MC may be continuously arranged in a vertical direction (Z-direction) and may constitute a cell string CS. The common source line CSL and the bit line BL may be connected to both ends of the cell string CS, as shown in the circuit diagram. Various voltages may be applied to the common source line CSL and the bit line BL so that programming, reading, and erasing operations may be performed on the plurality of memory cells MC.

For example, when the memory cells MC to be written is selected, a gate voltage value of a selected memory cell may be adjusted so that no channel may be formed in the selected memory cell, e.g., the selected memory cell is in a channel-off state, and gate voltage values of unselected memory cells may be adjusted so that the unselected memory cells are in a channel-on state. Thus, charges may be tunneled through the charge tunneling layer 123 by the voltage applied to the common source line CSL and the bit line BL and thus may be stored in the charge trap layer 122 of the selected memory cell MC and desired information of 1 or 0 may be recorded on the selected memory cell MC.

Even in the reading operation, similarly, reading of the selected cells may be performed. That is, after the gate voltage applied to each gate electrode 131 is adjusted so that the selected memory cell MC may be in a channel-off state and the unselected memory cells MC may be in a channel-on state, a current flowing through the corresponding memory cell MC may be measured by an applied voltage Vread between the common source line CSL and the bit line BL so that a memory cell state 1 or 0 may be checked.

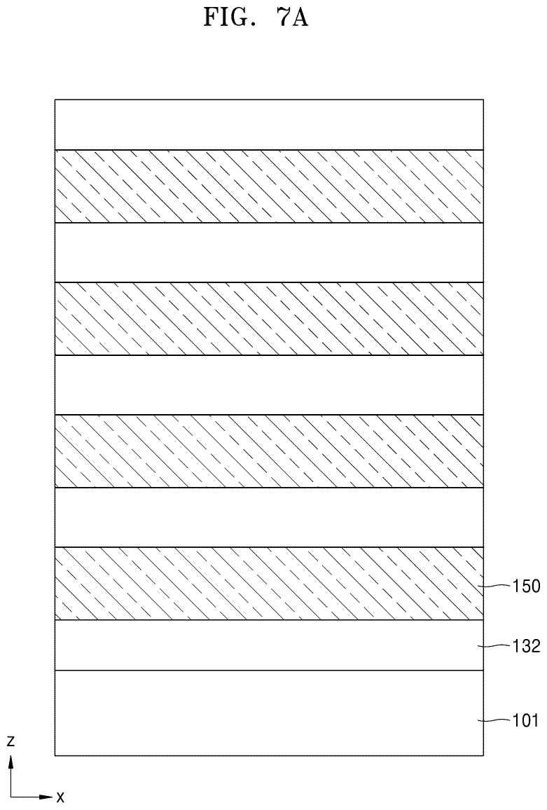

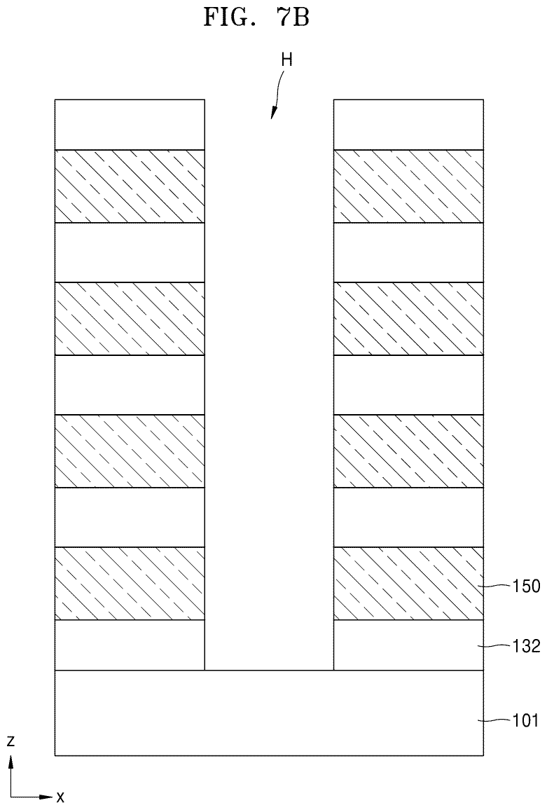

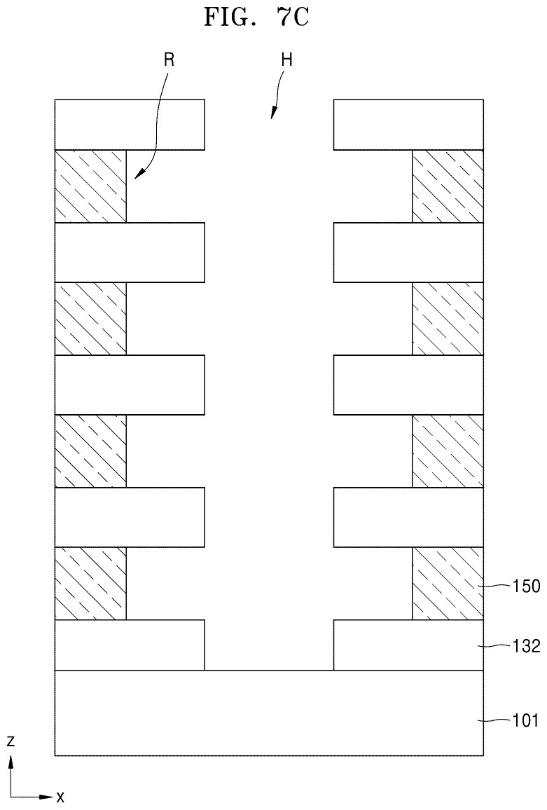

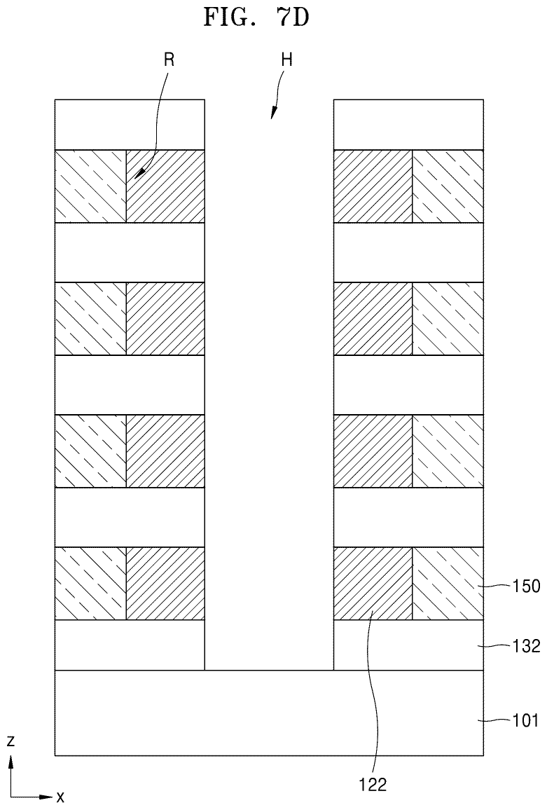

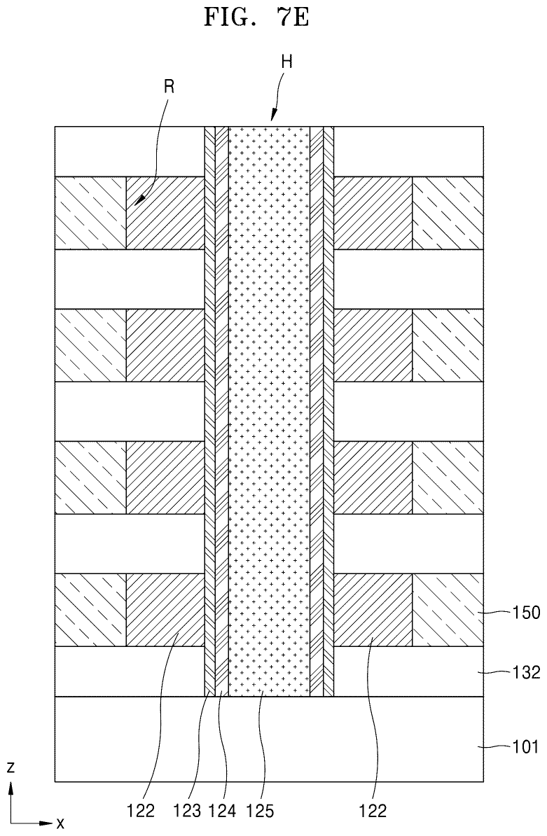

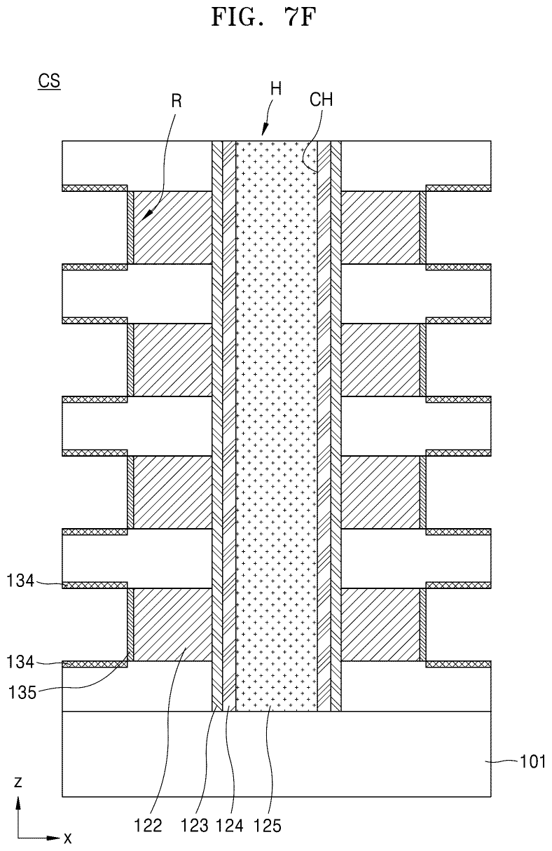

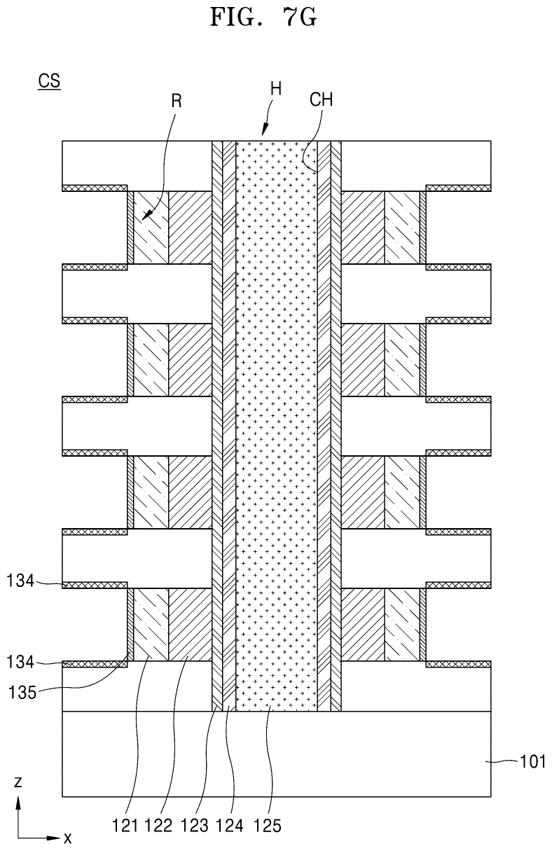

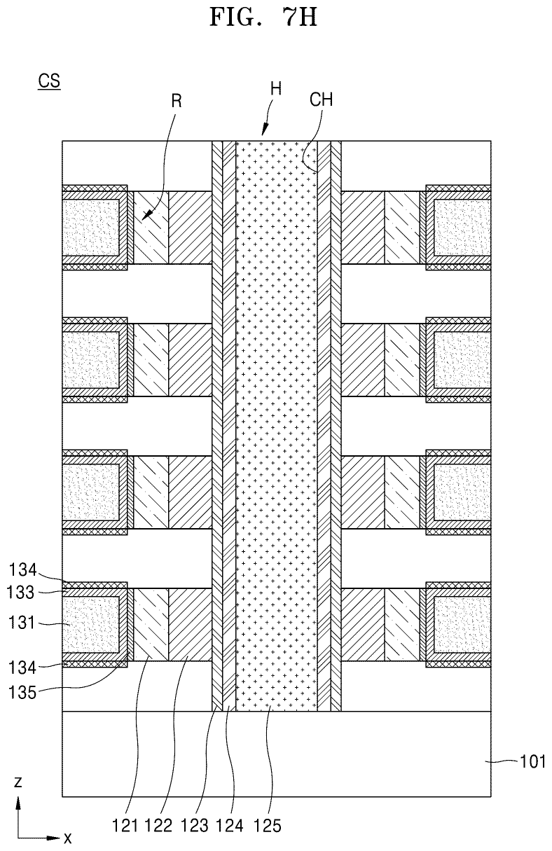

FIGS. 7A through 7H are views illustrating a method of manufacturing a vertical nonvolatile memory device according to some example embodiments.

Referring to FIG. 7A, a plurality of separation layers 132 and a plurality of semiconductor material layers 150 may be alternately stacked on a substrate 101. The substrate 101 may include a monocrystalline silicon substrate, a compound semiconductor substrate, or a SOI substrate. The plurality of separation layers 132 may include silicon oxide. The plurality of semiconductor material layers 150 may include one, two, or all three of Ge, Sn or carbon (C).

Different ones of the plurality of semiconductor layers 150 may have the same, or different concentrations of Ge, Sn, or C; example embodiments are not limited thereto. Alternatively or additionally, a concentration of each of Ge, Sn, or C included in the respective semiconductor layers 150 may be homogenous, or, alternatively, may be heterogeneous. In some cases, Ge, Sn, or C may be incorporated into the semiconductor layers 150 during a deposition process; alternatively or additionally, one or more of Ge, Sn, or C may be implanted into the respective semiconductor layers 150.

Referring to FIG. 7B, through holes H may be formed to pass through the plurality of separation layers 132 and the plurality of semiconductor material layers 150. The through holes H may extend onto an upper surface of the substrate 101. The through holes H may have a cylindrical shape or a tapered cylindrical shape, but embodiments are not limited thereto. The through holes H may be formed by an etching process such as a dry etching process.

Referring to FIG. 7C, a part of the plurality of semiconductor material layers 150 may be selectively etched at inner walls of the through holes H so that a plurality of recesses R may be formed. A part of the plurality of semiconductor material layers 150 may be removed by a gas etching process and/or a wet etching process, for example. In some cases, a wet etchant may be or may include phosphoric acid; alternatively or additionally a wet etchant may be or may include hydrofluoric acid.

Referring to FIG. 7D, a plurality of charge trap layers 122 may be formed to fill the plurality of recesses R. The charge trap layer 122 including silicon or silicon nitride may be selectively formed on a portion where the semiconductor material layers 150 are etched, through an area-selective atomic layer deposition (AS-ALD) process.

Referring to FIG. 7E, the charge tunneling layer 123, the channel layer 124, and the pillar 125 may be sequentially formed on the inner walls of the through holes H. The charge tunneling layer 123 may be formed on the inner walls of the through holes H having a cylindrical shape, for example. The charge tunneling layer 123 may include silicon oxide, for example. The charge tunneling layer 123 may be entirely formed on the inner walls of the through holes H. Thus, the charge tunneling layer 123 having a structure in which the plurality of memory cells MC shown in FIG. 2 are shared, may be formed. A method of forming the charge tunneling layer 123 is not specifically limited thereto. For example, the charge tunneling layer 123 may be formed by oxidizing (e.g., thermally oxidizing) the silicon charge trap layer 122, the charge tunneling layer 123 may also be formed through an ALD process, or the charge tunneling layer 123 may also be formed by using the above-described methods together.

The channel layer 124 may include one or more of Si, Ge, SiGe, a III-V-group semiconductor, an oxide semiconductor, a nitride semiconductor, an oxynitride semiconductor, a 2D semiconductor material, a quantum dot, or an organic semiconductor. The channel layer 124 may be formed of silicon, for example, and may be doped with impurities, if necessary or desirable. A method of forming the channel layer 124 is not specifically limited thereto, and for example, the channel layer 124 may be formed through an ALD method.

The pillar 125 may include, for example, silicon dioxide (SiO₂), air such as clean, dry air or the like, but embodiments are not limited thereto.

Referring to FIG. 7F, the plurality of remaining semiconductor material layers 150 may be etched. A region where the plurality of semiconductor material layers 150 are in contact with the separation layers 132 before the plurality of semiconductor material layers 150 are etched, may be referred to as a first region 134. The separation layers 132 may include one or more of Ge, Sn or C in the first region 134. The separation layers 132 may include 1 wt % or more of Ge, Sn, or C in the first region 134 where the separation layers 132 are in contact with the gate electrodes 131.

A region where the plurality of semiconductor material layers 150 are in contact with the charge blocking layers 121 before the plurality of semiconductor material layers 150 are etched, may be referred to as a second region 135. The charge blocking layers 121 may include Ge, Sn or C in the second region 135. The content of GE, Sn, or C in the second region 135 may be different from the content of GE, Sn, or C in the first region 134.

Referring to FIG. 7G, a part of an outside of the plurality of charge trap layers 122 may be oxidized to form the charge blocking layers 121. The charge blocking layers 121 may include silicon oxide, for example. In this case, the charge blocking layers 121 may be formed by oxidizing silicon of the charge trap layers 122 partially. In some examples, an outside region of the charge trap layers 122, e.g., an opposite region of the through holes H may be partially oxidized so that the charge blocking layers 121 may be formed. Thus, a process of manufacturing a vertical nonvolatile memory device may be simplified or improved upon.

Referring to FIG. 7H, gate electrodes 131 may be formed in a region in which the plurality of remaining semiconductor material layers 150 are etched. The gate electrodes 131 may include, for example, one or more of a metal material having good or excellent electrical conductivity, conductive oxide, metal nitride, silicon doped with impurities, or a 2D conductive material, or the like. A high-permittivity diffusion prevention layer 133 may be provided between the gate electrode 131 and the charge blocking layer 121. The high-permittivity diffusion prevention layer 133 may be provided between the gate electrode 131 and the separation layer 132. The high-permittivity diffusion prevention layer 133 may include, for example, one or more of AlO, HfO, ZrO, AlN, AlScN, AlBN, HfZrO, or HfSiO.

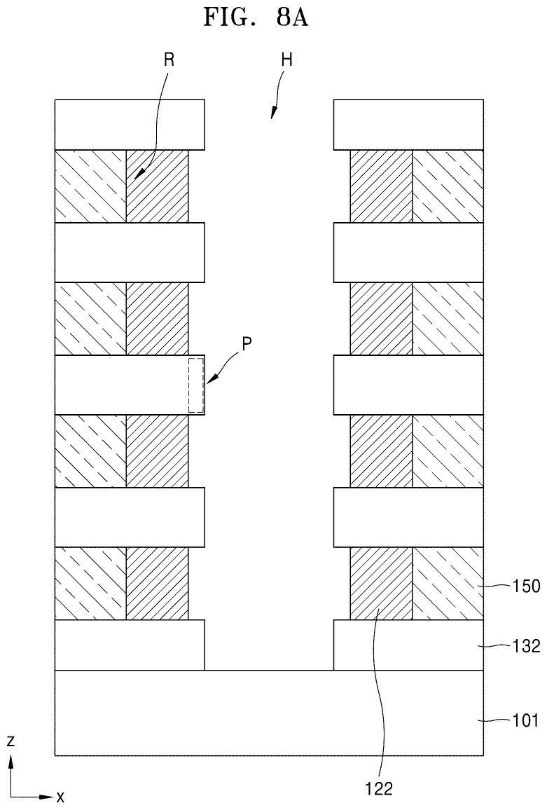

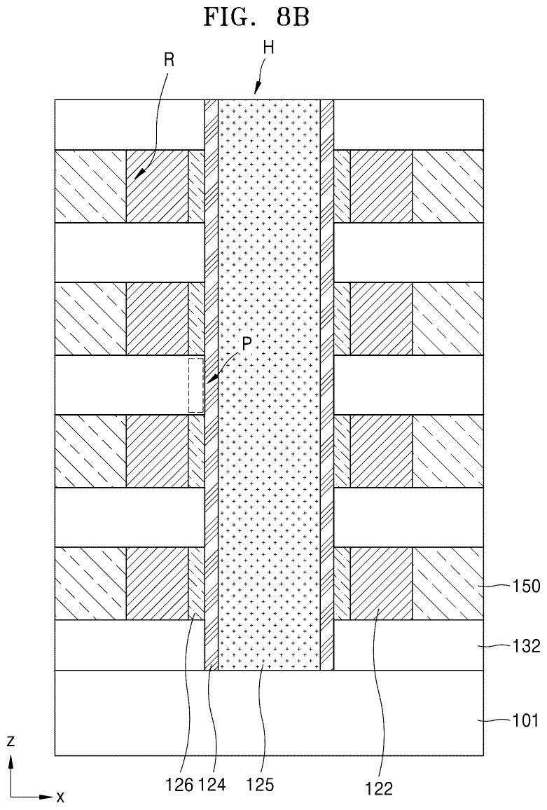

FIGS. 8A and 8B are views illustrating a part of a method of manufacturing a vertical nonvolatile memory device according to some example embodiments. In FIGS. 8A and 8B, the same reference numerals as those in FIGS. 1 and 2 represent the same elements, and repeated descriptions thereof will be omitted.

The processes described above with reference to FIGS. 7A through 7C may be performed before processes of FIGS. 8A and 8B are performed, and the processes described above with reference to FIGS. 7F and 7H may be performed after the processes of FIGS. 8A and 8B are performed.

Referring to FIG. 8A, a plurality of charge trap layers 122 may be formed to fill a plurality of recesses R. The plurality of charge trap layers 122 including silicon or silicon nitride may be selectively formed on a portion where the semiconductor material layers 150 are etched, through an area-selective atomic layer deposition (AS-ALD) process. When the plurality of charge trap layers 122 are formed, only a part of the plurality of recesses R may be filled so that protrusions P of the separation layers 132 may remain.

Referring to FIG. 8B, a charge tunneling layer 126 may be formed. The charge tunneling layer 126 may be formed to be in contact with the charge trap layer 122 between the protrusions P of the plurality of separation layers 132. The charge tunneling layer 126 may be formed by oxidizing the charge trap layer 122. The charge tunneling layer 126 may include the same material as a material for forming the separation layers 132. The plurality of charge tunneling layer 126 and the protrusions P of the plurality of separation layers 132 including the same material may extend in the z-axis direction, and the plurality of memory cells MC may share the charge tunneling layer 126.

The channel layer 124 and the pillar 125 may be sequentially formed at the inner walls of the through holes H. The channel layer 124 may include Si, Ge, SiGe, a III-V-group semiconductor, an oxide semiconductor, a nitride semiconductor, an oxynitride semiconductor, a two-dimensional (2D) semiconductor material, a quantum dot, or an organic semiconductor. The channel layer 124 may be formed of silicon, for example, and may be doped with impurities, if necessary or desirable. A method of forming the channel layer 124 is not specifically limited thereto, and for example, the channel layer 124 may be formed through an ALD method. The pillar 125 may include, for example, silicon dioxide (SiO₂), air such as clean, dry air or the like, but embodiments are not limited thereto.

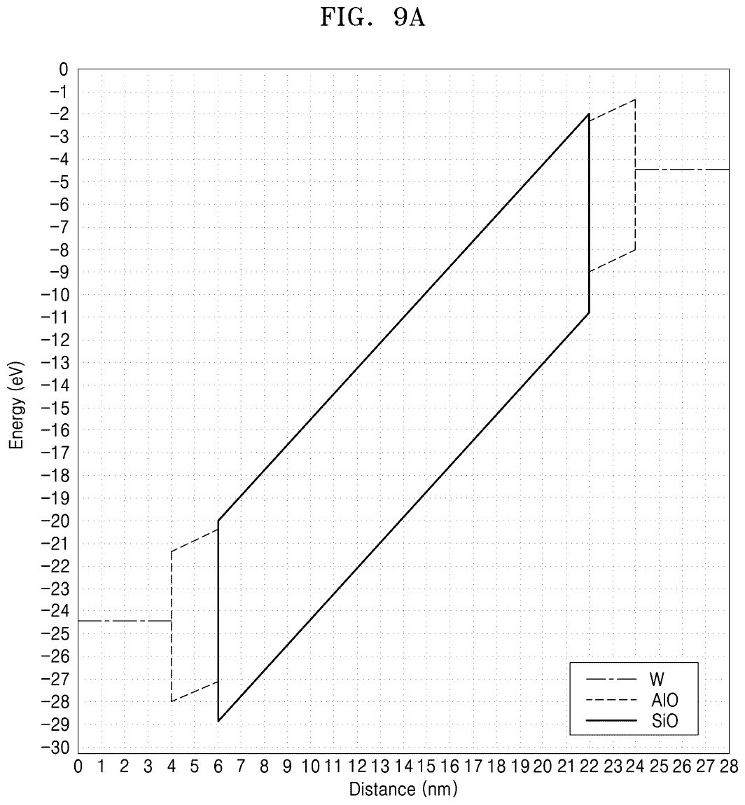

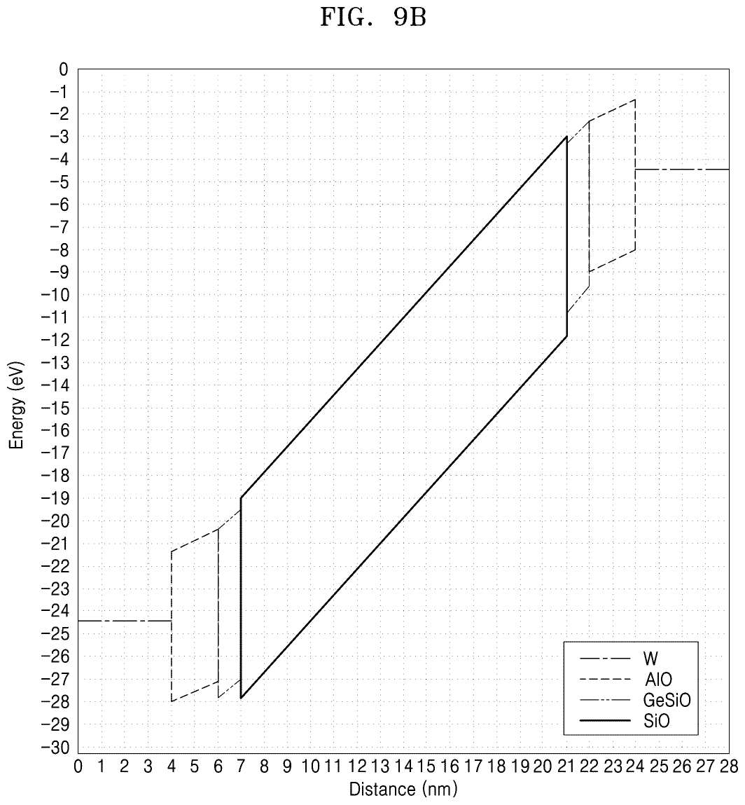

FIGS. 9A and 9B are graphs showing a reduction in leakage current of an interlayer insulating layer of a memory device according to a comparative example and some example embodiments, respectively.

Comparative example 1 illustrates a memory device in which tungsten (W) is used as the gate electrode 131, AlO is used as the high permittivity diffusion prevention layer 133 and SiO is used as the separation layer 132, and Embodiment 1 illustrates a memory device in which W is used as the gate electrode 131, AlO is used as the high permittivity diffusion prevention layer 133 and GeSiO is formed between the gate electrode 131 and the high permittivity diffusion prevention layer 133.

Referring to FIG. 9A, in Comparative example 1, the thickness of a separation layer is measured 16 nm. The thickness of the separation layer represents an electrical field applied to the separation layer, and as the thickness of the separation layer decreases, a leakage current decreases.

FIG. 9B illustrates measurement of an electrical field applied taken along a line B-B′ of FIG. 2. Referring to FIG. 9B, in Embodiment 1, the thickness of a SiO separation layer is measured 14.4 nm. GeSiO having a thickness of 1 nm may be formed between the gate electrode and the high permittivity diffusion prevention layer, and thus, the thickness of the separation layer may be reduced from 16 nm to 14.6 nm. Thus, the leakage current of the separation layer may be decreased when GeSiO is formed between the gate electrode and the high permittivity diffusion prevention layer.

A vertical nonvolatile memory device according to some example embodiments may be applied to various electronic apparatuses.

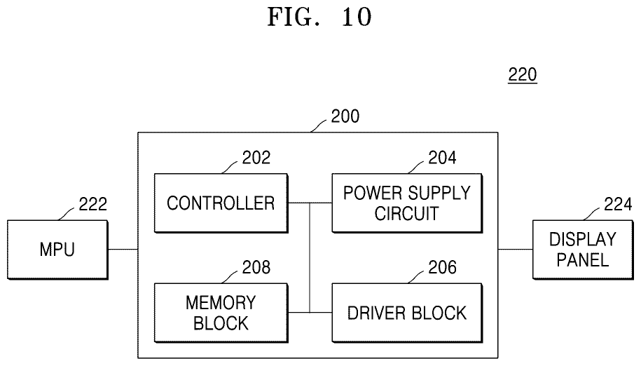

FIG. 10 is a schematic block diagram of a display driver integrated circuit (IC) (DDI) 200 and a display apparatus 220 including the DDI 200 according to some example embodiments.

Referring to FIG. 10, the DDI 200 may include a controller 202, a power supply circuit 204, a driver block 206, and a memory block 208. The controller 202 may receive and decode instructions applied from a main processing unit (MPU) 222 and may control blocks of the DDI 200 so as to implement an operation according to the instructions. The power supply circuit 204 may generate a driving voltage in response to control of the controller 202. The driver block 206 may drive a display panel 224 using a driving voltage generated by the power supply circuit 204 in response to control of the controller 202. The display panel 224 may be, for example, one or more of a liquid crystal display panel, an organic light emitting device (OLED) display panel, or a plasma display panel. The memory block 208 may be a block for storing instructions input to the controller 202 or control signals output from the controller 202 temporarily, or storing necessary pieces of data and may include memory such as one or more of random access memory (RAM), read only memory (ROM) or the like. For example, the memory block 208 may include the vertical nonvolatile memory device 100 according to one or more of the above-described example embodiments.

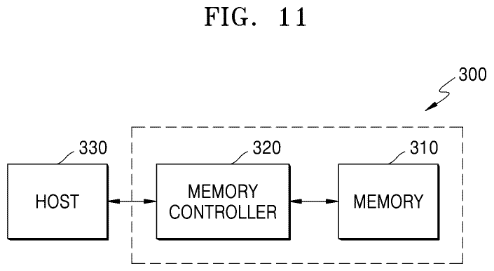

FIG. 11 is a block diagram illustrating an electronic apparatus 300 according to some example embodiments.

Referring to FIG. 11, the electronic apparatus 300 may include memory 310 and a memory controller 320. The memory controller 320 may control the memory 310 so as to read data from the memory 310 and/or to write data to the memory 310 in response to a request of a host 330. The memory 310 may include the vertical nonvolatile memory device 100 according to the above-described example embodiments.

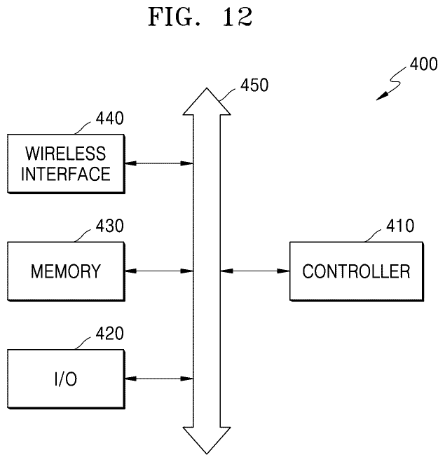

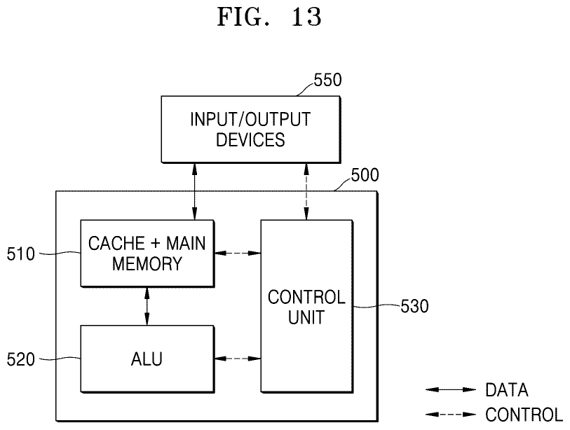

FIG. 12 is a block diagram illustrating an electronic apparatus 400 according to some example embodiments. Referring to FIG. 13, the electronic apparatus 400 may constitute a wireless communication apparatus or an apparatus capable of transmitting and/or receiving information in a wireless environment. The electronic apparatus 400 may include a controller 410, an input/output device (I/O) 420, memory 430, and a wireless interface 440, and these elements may be connected to each other via a bus 450.

The controller 410 may include at least one of a microprocessor, a digital signal processor, or a processing apparatus similar thereto. The I/O 420 may include at least one of a keypad, a keyboard, and a display. The memory 430 may be used to store instructions executed by the controller 410. For example, the memory 430 may be used to store user data. The electronic apparatus 400 may use the wireless interface 440 so as to transmit/receive data via a wireless communication network. The wireless interface 440 may include an antenna and/or a wireless transceiver. In some example embodiments, the electronic apparatus 400 may be used as a communication interface protocol for a third generation communication system such as one or more of a code division multiple access (CDMA), a global system for mobile communications (GSM), north American digital cellular, extended-time division multiple access (E-TDMA) and/or a wide band code division multiple access (WCDMA). The memory 430 of the electronic apparatus 400 may include the vertical nonvolatile memory device 100 according to the above-described embodiments.

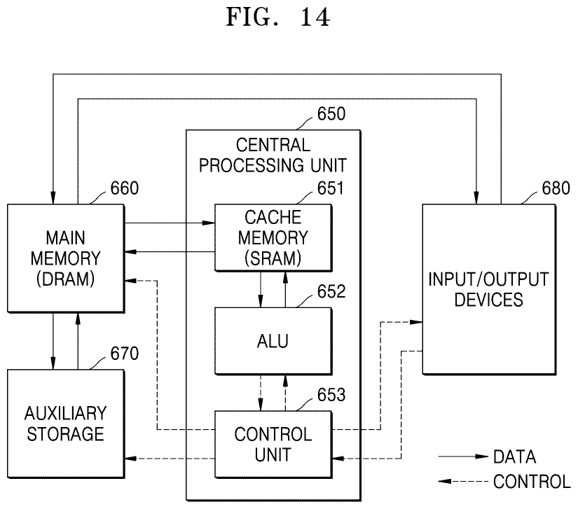

FIGS. 13 and 14 are conceptual views schematically illustrating a device architecture that may be applied to an electronic apparatus according to some example embodiments.

Referring to FIG. 13, an electronic device architecture 500 may include a memory unit 510 and a control unit 530, and may further include an arithmetic logic unit (ALU) 520. The memory unit 510, the ALU 520, and the control unit 530 may be electrically connected to each other. For example, the electronic device architecture 500 may be implemented with one chip including the memory unit 510, the ALU 520, and the control unit 530. Specifically, the memory unit 510, the ALU 520, and the control unit 530 may be connected to each other via a metal line in an on-chip and may directly communicate with each other. The memory unit 510, the ALU 520, and the control unit 530 may be monolithically integrated on one substrate (101 of FIG. 1) and may constitute one chip. Input/output devices 550 may be connected to the electronic device architecture 500. Also, the memory unit 510 may include both main memory and cache memory. The electronic device architecture 500 may be or may include (or be included in) an on-chip memory processing unit. Each of the memory unit 510, the ALU 520 and/or the control unit 530 may include the vertical nonvolatile memory device 100 according to the above-described example embodiments.

Referring to FIG. 14, cache memory 651, the ALU 652, and the control unit 653 may constitute a central processing unit (CPU) 1500, and the cache memory 651 may include static random access memory (SRAM). Apart from the CPU 650, the main memory 660 and the auxiliary storage 670 may be provided, and also may be provided with the input/output device 680. The main memory 660 may be, for example, a dynamic RAM (DRAM), and may include the vertical nonvolatile memory device 100 according to the above-described embodiments.

In some cases, the electronic device architecture may be implemented in a shape in which computing unit elements and memory unit elements are arranged adjacent to one another in one chip regardless of classification of sub-units.

The vertical nonvolatile memory device according to various example embodiments may be applied to various user apparatuses such as one or more of a computer, a portable computer, an ultra mobile personal computer (PC), a workstation, a net-book, a portable digital assistant (PDA), a portable computer, a web tablet, a wireless phone, a mobile phone, a smart phone, a digital camera, a digital audio recorder, a digital audio player, a digital picture recorder, a digital picture player, a digital video recorder, a digital video player, an apparatus capable of transmitting/receiving information in a wireless environment, and a home network.

In a vertical nonvolatile memory device and a method of manufacturing the same according to the inventive concept, a charge trap layer can be discontinuously formed through selective growth so that the charge trap layer can be prevented from being connected to an adjacent charge trap layer and thus high charge retention characteristics can be obtained. The vertical nonvolatile memory device and the method of manufacturing the same have been described by reference to the embodiments shown in the drawings, but this is just an example, and it will be understood by those skilled in the art that a variety of modifications and other equivalent embodiments therefrom are possible. Thus, the disclosed embodiments should be considered not in a limited viewpoint but in a descriptive viewpoint. The scope of the rights is not described above, but in the claim of the claim, and all the differences in the same range should be interpreted as included in the range of rights.

In a memory device according to some example embodiments, charge trap layers are discontinuously formed through selective growth so that the charge trap layers can be prevented from being connected to adjacent charge trap layers. Thus, high charge retention characteristics can be obtained.

In a memory device according to some example embodiments, leakage current characteristics can be enhanced, and the thickness of the memory device is decreased so that operating characteristics of the memory device can be enhanced.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, one or more of a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

It should be understood that example embodiments described herein should be considered in a descriptive sense only and not for purposes of limitation. Descriptions of features or aspects within each embodiment should typically be considered as available for other similar features or aspects in other embodiments. For example, variously described example embodiments are not necessarily mutually exclusive, and in some cases may include one or more features described with reference to one or more figures and also one or more other features described with reference to one or more other figures.

While one or more example embodiments have been described with reference to the figures, it will be understood by those of ordinary skill in the art that various changes in form and details may be made therein without departing from the spirit and scope as defined by the following claims.

What is claimed is:

1. A memory device comprising a plurality of cell strings, wherein each of the plurality of cell strings comprises:
a channel layer;
a charge tunneling layer outside the channel layer in a lateral direction perpendicular to a longitudinal direction of the channel layer;
a plurality of charge trap layers in the longitudinal direction outside the charge tunnel layer in the lateral direction and spaced apart from the charge tunneling layer in the longitudinal direction;
a plurality of charge blocking layers in the lateral direction respectively outside the plurality of charge trap layers;
a plurality of gate electrodes in the lateral direction respectively outside the plurality of charge trap layers; and
a plurality of separation layers in the longitudinal direction configured to isolate the plurality of charge trap layers, the plurality of charge blocking layers, and the plurality of gate electrodes from each other, wherein
the plurality of separation layers each independently comprise at least one of germanium (Ge), tin (Sn) or carbon (C) in a region where the plurality of separation layers are in contact with the plurality of gate electrodes.

2. The memory device of claim 1, wherein the plurality of separation layers each independently comprise 1 wt % or more of at least one of Ge, Sn or C in a region where the plurality of separation layers are in contact with the plurality of gate electrodes.

3. The memory device of claim 1, wherein the plurality of charge blocking layers each independently comprise at least one of Ge, Sn or C in a region where the plurality of charge blocking layers are in contact with the plurality of gate electrodes.

4. The memory device of claim 3, wherein the plurality of charge blocking layers each independently comprise 1 wt % or more Ge, Sn or C in a region where the plurality of charge blocking layers are in contact with the plurality of gate electrodes.

5. The memory device of claim 1, wherein the plurality of charge trap layers each independently comprise at least one of silicon or silicon nitride.

6. The memory device of claim 1, wherein the plurality of charge trap layers are spaced apart from each other in a vertical direction.

7. The memory device of claim 1, wherein a thickness of each of the plurality of charge trap layers in the longitudinal direction is greater than a thickness of any of the plurality of gate electrodes in the longitudinal direction.

8. The memory device of claim 1, wherein the plurality of charge tunneling layers extend in a longitudinal direction of the channel layer shared with the plurality of charge trap layers.

9. The memory device of claim 1, wherein a thicknesses deviation of the plurality of charge tunneling layers in the lateral direction is about 5 nm or less.

10. The memory device of claim 1, further comprising:
a high-permittivity diffusion reduction layer between the gate electrode and the charge blocking layer.

11. The memory device of claim 10, wherein the high-permittivity diffusion blocking layer comprises at least one of AlO, HfO, ZrO, AlN, AlSCN, AlBN, HfZrO or HfSiO.

12. The memory device of claim 1, wherein the plurality of separation layers each comprise silicon oxide.

13. The memory device of claim 12, wherein the plurality of separation layers each independently further comprise at least one of hydrogen (H), C, and nitrogen (N).

14. The memory device of claim 1, wherein the plurality of charge tunneling layers each comprise silicon oxide.

15. The memory device of claim 1, wherein the plurality of charge blocking layers each comprise an oxide of a material of the plurality of charge trap layers.

16. A method of manufacturing a memory device, the method comprising:
stacking a plurality of separation layers and a plurality of semiconductor material layers alternately on a substrate;
forming through holes passing through the plurality of separation layers and the plurality of semiconductor material layers;
forming a plurality of recesses by selectively etching a part of the plurality of semiconductor material layers at inner walls of the through holes;
forming a plurality of charge trap layers for filling the plurality of recesses;
sequentially forming a charge tunneling layer and a channel layer at the inner walls of the through holes;
etching the plurality of remaining semiconductor material layers;
forming a plurality of charge blocking layers by oxidizing a part of an outside of the plurality of charge trap layers; and
forming a plurality of gate electrodes in a region where the plurality of remaining semiconductor material layers are etched,
wherein each of the plurality of separation layers independently comprises at least one of germanium (Ge), tin (Sn) or carbon (C) in a region where the plurality of separation layers are in contact with the plurality of gate electrodes.

17. The method of claim 16, wherein the plurality of separation layers each independently comprise 1 wt % or more of at least one of Ge, Sn or C in a region where the plurality of separation layers are in contact with the plurality of gate electrodes.

18. The method of claim 16, wherein the forming of the charge tunneling layer comprises forming the charge tunneling layer by oxidizing the charge trap layers.

19. The method of claim 16, wherein the forming of the charge tunneling layer comprises forming the charge tunneling layer through an atomic layer deposition (ALD) process.

20. An electronic apparatus comprising:
memory; and
a memory controller configured to control the memory so as to at least one of read data from the memory or to write data to the memory, wherein
the memory comprises the memory device of claim 1.
